(19) United States
(12) Patent Application Publication
(10) Pub. No.: US 2019/0164761 A1
(43) Pub. Date: May 30, 2019

(54) METHOD FOR DOPING SILICON SHEETS

(71) Applicant: ION BEAM SERVICES, Peynier (FR)

(72) Inventors: Bernard BECHEVET, Habere-Poche (FR); Johann JOURDAN, Chambery (FR)

(73) Assignee: ION BEAM SERVICES, Peynier (FR)

(21) Appl. No.: 16/249,130

(22) Filed: Jan. 16, 2019

Related U.S. Application Data
(62) Division of application No. 14/777,798, filed on Sep. 17, 2015, now abandoned.

(30) Foreign Application Priority Data
Mar. 20, 2013 (FR) 1300650

(51) Int. Cl. H01L 21/223; H01L 31/068; H01L 31/18

(52) U.S. Cl. CPC H01L 21/2236; H01L 31/068; Y02E 10/547; H01L 31/186; Y02P 70/521; H01L 31/1804

(57) ABSTRACT

A method of doping a silicon wafer in order to fabricate a photovoltaic cell, the method including the steps of: performing a first doping operation of at least a first portion (11) of a surface (10) of the silicon wafer; forming an oxide layer (40) on the partially doped surface (10); and performing a second doping operation through the oxide layer (40), so as to dope another portion (12) of the surface (10) of the silicon wafer.

This application is a Divisional of U.S. application Ser. No. 14/777,798 filed Sep. 17, 2015 which is a National Stage of International Application No. PCT/EP2014/055621 filed Mar. 20, 2014, claiming priority based on French Patent Application No. 1300650 filed Mar. 20, 2013, the contents of all of which are incorporated herein by reference in their entirety.

### BACKGROUND OF THE INVENTION

The present invention relates in general manner to doping silicon wafers that are to form photovoltaic cells for mounting in a solar panel.

In the prior art, it is known to dope silicon wafers sequentially in order to obtain photovoltaic cells: in order to perform localized n or p doping (referred to as doping tubs or wells), present-day technologies make use either of lithographic technologies as used in microelectronics or else laser ablation, or indeed localized laser annealing. Unfortunately, all of those techniques are either expensive (number of process steps) or else they are not automatically aligned (in other words it is necessary to take a geometrical reference from the silicon wafer before each doping operation in order to guarantee that portions that are doped subsequently do not overlap with portions that have already been doped, and remain clearly distinct). Thereafter, it is often necessary (when the doped portions are made by implantation) to perform activation co-annealing at raised temperature, which is very difficult to arrange since the activation temperatures are different between the n portions (e.g. doped with phosphorus) and the p portions (e.g. doped with boron). It is also possible to envisage doping using the following species: aluminum, gallium; indium, arsenic; or antimony.

### SUMMARY OF THE INVENTION

An object of the present invention is to respond to the above-mentioned drawbacks of the prior art and in particular, firstly to propose a method of sequentially doping a plurality of distinct portions of a silicon wafer but that does not require sophisticated equipment or a specific operation of localization in order to avoid overlap between doped portions.

To do this, in a first aspect, the invention provides a method of doping a silicon wafer in order to fabricate a photovoltaic cell, the method comprising the steps consisting in:
performing a first doping operation of at least a first portion of a surface of the silicon wafer;
forming an oxide layer on the partially doped surface; and
performing a second doping operation through the oxide layer, so as to dope another portion of the surface of the silicon wafer.

The method of the present implementation uses a property that is well known in microelectronics, concerning the speed of growth of oxides on silicon. This speed of growth of silicon oxide (SiO₂) is faster on the first portions of the surface that have been exposed to the first doping operation. In other words, the oxide layer is thicker over the doped first portions than over the remainder of the surface of the silicon wafer, thus presenting an additional barrier to the second doping operation. As a result, the second doping operation, which is performed over the entire oxide layer, is effective only over a fraction of the remainder of the surface of the silicon wafer, since it is performed in such a manner as to be capable of penetrating through the thin oxide layer but not through the thick oxide layer in register with the doped first portions. As a result, the oxide layer acts as a mask during the second doping operation, with this mask naturally covering the doped first portions. This ensures that doped second portions are automatically in alignment with the doped first portions, because of the oxide layer formed on the surface of the silicon wafer prior to the second doping operation. There is thus no mask applied to the silicon wafer prior to the second doping operation in order to obtain doped zones of different kinds. There is likewise no cleaning or removal of oxides between the first and second doping operations, thereby improving the overall fabrication process and simplifying the fabrication line.

For example, if the first doping operation consists in obtaining doped lines that are spaced apart, then the second doping operation does not penetrate the oxide layer in register with the doped first portions (because the oxide layer is locally thicker), but it does pass through the oxide layer formed between the doped first portions (since the oxide layer is locally thinner over the non-doped silicon), and the silicon wafer is thus doped in those locations. It is thus possible, without using a mask and without using any intermediate cleaning operation, to obtain doped second portions that are lines that are automatically aligned relative to the first doped portions.

In general, there is thus no partial cleaning or etching of the oxide layer formed after the first doping operation in order to perform the second doping operation over only a fraction of the silicon wafer. It is the oxide layer that forms the mask without using any specific operation, since oxide formation is thicker over the portions of silicon that have been subjected to the first doping operation. The method is thus characterized by its small number of operations.

In an implementation, the step consisting in forming an oxide layer is included in a step of activation annealing the doped first portion. The activation annealing of the doped first portions is advantageously combined with forming the oxide layer. A single step serves both to activate the doped first portion and to provide the oxide layer.

In an implementation, the step consisting in forming an oxide layer comprises a step of heating in an oxygen-enriched atmosphere. The formation of the oxide layer is accelerated and better controlled.

In an implementation, the step consisting in performing the second doping operation is a step consisting in performing doping to a predetermined penetration depth.

In an implementation, the step consisting in forming an oxide layer is a step leading to forming a first thickness of oxide in register with the doped first portion and a second thickness of oxide over the remainder of the surface, the second thickness of oxide being less that the first thickness of oxide; and the penetration depth lies between the first thickness of oxide and the second thickness of oxide. The present implementation guarantees an optimized method. The second doping operation does not affect the doped first portions, since it does not pass through the thick zones of the oxide layer, and it reaches the non-doped portions of silicon wafer since it does pass through the thin zones of the oxide layer.

In an implementation, the step consisting in performing the first doping operation is performed in plasma immersion. This step of the method may be performed using equipment that is simpler than a plasma gun, for example.

In an implementation, the step consisting in performing the second doping operation is performed in plasma immersion. This step of the method may be performed with equipment that is simpler than a plasma gun, for example.

In an implementation, the step consisting in performing the first doping operation and/or the step consisting in performing the second doping operation is performed in plasma immersion.

In an implementation, the step consisting in performing the second doping operation is followed by a step of activation annealing the second doping. The operation of the photovoltaic cell is thus optimized.

In an implementation, the step consisting in performing the first doping operation is a step of doping the silicon with a first species that requires activation annealing at a first temperature, and the step consisting in performing the second doping operation is a step of doping the silicon with a second species that requires activation annealing at a second temperature, lower than the first temperature. Each doping operation requires an activation anneal at a specific temperature. As a result of this implementation, since the temperature of the second activation anneal is lower than the temperature of the first activation anneal, the second anneal has no influence on the properties of the doped first portions.

In an implementation, the step consisting in performing the first doping operation is a step of doping the silicon with boron, and the step consisting in performing the second doping operation is a step of doping the silicon with phosphorus. Each doping operation requires an activation anneal at a specific temperature. The ideal temperature for annealing boron doping is higher than that for an activation anneal of phosphorus. As a result of this implementation, since the temperature of the second activation anneal is lower than the temperature of the first activation anneal, the second anneal has no influence on the properties of the doped first portions.

In an implementation, the step consisting in performing a second doping operation is followed by a step consisting in removing the oxide layer. This step consists in removing the entire oxide layer in a single step, such that the cell is then ready for the subsequent steps of fabrication of the photovoltaic cell.

In an implementation, the step consisting in removing the oxide layer is a step of chemical deoxidation in a bath comprising hydrofluoric acid. This implementation is fast and simple, with all of the silicon oxide layer being removed in a single step, without taking any special precautions.

In a second aspect, the invention provides a photovoltaic cell presenting doping performed in accordance with the first aspect of the invention.

In a last aspect, the invention provides a solar panel including at least one photovoltaic cell in accordance with the second aspect of the invention.

### BRIEF DESCRIPTION OF THE DRAWINGS

Other characteristics and advantages of the present invention appear more clearly on reading the following detailed description of an embodiment of the invention given by way of non-limiting example and illustrated in the accompanying drawings, in which:

FIG. 1 is a section view of a silicon wafer during a first step of the method of the invention;

FIG. 2 is a section view of the FIG. 1 silicon wafer during a second step of the method of the invention; and

FIG. 3 is a section view of the FIG. 1 silicon wafer during a third step of the method of the invention.

### DETAILED DESCRIPTION OF THE INVENTION

Growing silicon oxide on a partially doped silicon wafer is described in a publication by E. Biermann: “Silicon oxidation rate dependence on dopant pile-up”, Solid State Device Research Conference, 1989. ESSDERC '89. 19th European, Vol., No., pp. 49, 52, 11-14 Sep. 1989.

The abstract may be found at the following URL: http://ieeeplore.ieee.org/stamp/stamp.jsp?tp=&arnumber=54 36671&isnumber=5436370

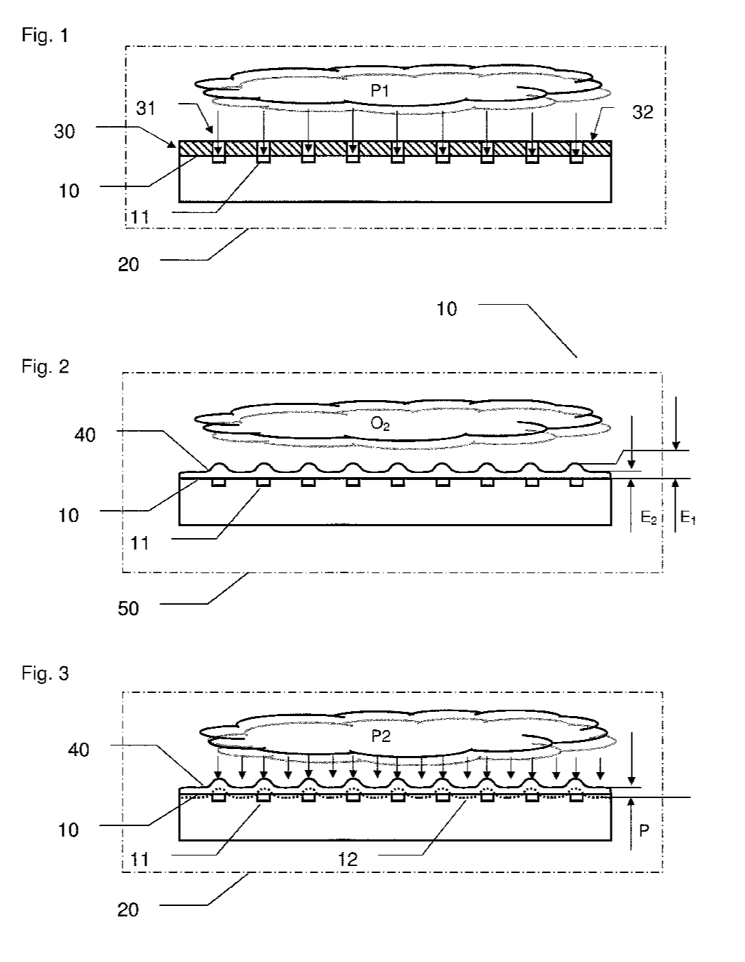

FIG. 1 shows a section view of a silicon wafer during a first step of the method of the invention.

This first step consists in doping first portions 11 of a surface 10 of the silicon wafer with a first chemical species. The doping method used is plasma immersion doping P1, as described for example in Document WO 2012/168575 A2. In order to perform a first partial doping operation, the silicon wafer is placed in a plasma chamber 20 and a mask 30 is applied to the face 10 of the silicon wafer. The mask 30 has openings 31 and solid portions 32 for the purpose of allowing the plasma generated in the plasma chamber 20 to immerse only the first portions 11 of the silicon wafer that are in register with the openings 31 in the mask 30. In order to implant the first ionized chemical species in the chamber 20, a voltage is applied to the silicon wafer so that an electric field forces the ions of the first chemical species to become implanted in the silicon wafer, in the first portions 11 that are left free by the openings 31 in the plate 30, as represented by the arrows shown.

As shown in FIG. 1, the silicon wafer is thus doped with a first chemical species on the first portions 11 of the silicon wafer.

FIG. 2 shows a second step of the method of the invention, during which an oxide layer 40 is created on the silicon 10 of the partially doped silicon wafer. Since the surface 10 presents doped first portions 11, the properties of the surface 10 are heterogeneous, in particular concerning reactivity with oxygen. Oxides are created more quickly on the first portions 11 than on the remainder of the surface 10 of the silicon wafer.

The second step of the method comprises exposing the surface 10 to oxygen O₂ in an enclosure 50 at raised temperature in order to accelerate the growth of silicon dioxide on the surface 10. While the oxide layer 40 is being created on the surface 10 of the silicon wafer, growth thus takes place more quickly on the doped first portions 11 than on the remainder of the surface 10 of the silicon wafer. The Applicant has found that the thickness of the oxide layer 40 is two to three times greater over the doped first portions 11 than over the remainder of the surface 10, e.g. if the first doping operation is performed using boron or phosphorus.

The step of creating the oxide layer 40 is controlled in terms of time, temperature, and oxygen flow rate in order to obtain an oxide layer 40 that has a first thickness E1 lying in the range 10 nanometers (nm) to 60 nm over the doped first portions 11, and a second thickness E2 lying in the range 4 nm to 20 nm over the remainder of the surface 10. At the transitions between the doped first portions 11 and the remainder of the surface 10 of the silicon wafer, the thickness of the oxide layer 40 passes progressively from the large first thickness to the small second thickness, as shown in FIG. 2.

In order to increase the efficiency of the photovoltaic cell that is to be fabricated using the silicon wafer, it is necessary to activate the doped first portions 11 with a raised temperature activation anneal, and an ingenious implementation consists in incorporating the step of creating the oxide layer 40 during the raised temperature activation anneal step.

FIG. 3 shows a third step of the method of the invention. A second doping operation is performed, directly on the oxidized silicon wafer, through the oxide layer 40. For this purpose, it is possible to perform a new plasma immersion step P2 in the chamber 20, but this time without the mask on the silicon wafer, since the method of the invention makes use of the oxide layer 40 as a mask. An electric field is likewise created in the chamber 20, by applying a voltage to the silicon wafer so that the ions present in the plasma in the plasma chamber 20 are projected against the silicon wafer, as represented by the arrows shown. It is important to guarantee that the second doping operation reaches the surface 10 of the silicon wafer over only a fraction of the remainder of the surface 10, and without reaching the doped first portions 11, nor the portions of the surface 10 that are immediately adjacent to the first portions 11. For this purpose, the parameters of the second doping operation, such as the voltage applied to the silicon wafer, the precursor gas flow rate, the ionization current, and the pressure that exists in the plasma chamber 20, are all controlled in such a manner that the second doping operation passes through the oxide layer 40 where it is thin, but not through the oxide layer 40 where it is thick. The above-mentioned control of parameters makes it possible to obtain a penetration depth during the second doping operation that is greater than the second thickness of the oxide layer 40, but less than the first thickness of the oxide layer 40. The second doping operation is thus:
strictly limited to the oxide layer 40 in register with the doped first portions 11, and in their immediate proximity; and
passes completely through the oxide layer 40 and penetrates into a portion of the silicon wafer over the remainder of the surface 10.

As represented in FIG. 3 by dashed lines, at the end of the second doping operation, the silicon wafer presents first portions 11 that were doped during the first doping operation, and second portions 12 that were doped during the second doping operation, which portions are separated by third portions that are not doped. The above-described method makes it possible to obtain second doping that is automatically in register with the first doping, without any overlap between doped portions.

The method of the invention may then include a step that consists in removing the oxide layer 40. By way of example, this operation may be performed by chemical deoxidation, e.g. using immersion in a bath of hydrofluoric acid (the oxide layer 40 is totally dissolved on passing in the bath). This passage in a bath is simple to perform, since it suffices to immerse the silicon wafer for longer than some minimum length of time required for complete dissolution, while ensuring that the concentration of the acid is sufficient. Draining and drying then suffices prior to moving on to a subsequent step in the fabrication method.

Furthermore, in order to guarantee good efficiency for the photovoltaic cell that is to be obtained using the silicon wafer, it is possible to perform raised temperature activation annealing of the second doping.

The method of the invention thus makes it possible to separate the two activation annealing steps, such that the temperatures selected for them can be well matched to each of the doping species that is to be activated.

A preferred implementation of the invention consists in performing the first doping operation with a first chemical species that requires a first activation anneal at a first temperature, and to perform the second doping operation with a second chemical species that requires a second activation anneal at a second temperature that is lower than the first temperature.

During the first anneal, this implementation makes it possible to benefit from the higher temperature in order to form the oxide quickly, and during the second activation anneal it makes it possible to avoid influencing the activation of the doped first portions since their activation temperature is not reached.

An example of a method for fabricating a photovoltaic cell is described below.

1. Silicon wafers are textured/polished (e.g. texturing in the range 5 micrometers (μm) to 15 μm, and polishing in the range 5 μm to 15 μm).

2. Boron first doping is performed using masked implantation on the rear face.

3. Activation annealing of the first doping and oxidation of the silicon wafer.

During this step, it is possible to anneal the silicon wafer at about 950° C., and during this anneal, exposing the silicon wafer for 17 minutes (min) to oxygen will lead to an oxide layer being grown having a thickness of about 10 nm on the non-doped portion of the silicon wafer, in compliance with the equations and constants taken from a publication by B. E. Deal “Semiconductor materials and process technology handbook: for very large-scale integration (VLSI) and ultra-large scale integration (ULSI)”, published by Gary E. McGuire (pp. 48-57). The oxide layer on the doped portions will be about 20 nm to 30 nm thick.

4. Phosphorus second doping operation by full surface implantation on the front and rear faces.

The second doping step as applied to the rear face can thus be performed in plasma immersion with the voltage applied to the silicon wafer lying in the range 1 kilovolts (kV) to 20 kV, with pressure in the chamber lying in the range 10⁻² millibars to 10⁻⁷ millibars, and with an ionization current of 200 milliamps (mA) in order to pass through the 10 nm of the oxide layer in register with the portions that were not doped during the first doping operation, while not passing through the 20 nm to 30 nm thick oxide layer in register with the portions that were doped during the first doping operation.

5. Removing the oxide layer in a hydrofluoric acid bath at a concentration lying in the range 0.5% to 20% for a duration lying in the range 1 second (s) to 120 s.

6. Activation/oxidation anneal of the second doping at about 850° C. for 10 min to 60 min.

7. Depositing a passivation/isolation layer on the rear face (e.g. a layer of Si₃N₄ having thickness lying in the range 20 nm to 220 nm).

8. Depositing a passivation/anti-reflection layer on the front face (e.g. Si₃N₄ with a thickness lying in the range 50 nm to 90 nm).

9. Making contact with the fingers by silk-screen printing and annealing (silver pastes with frit on the fingers and without frit on the collectors, annealing at a temperature in the range 750° C. to 950° C. for a period in the range 1 s to 60 s).

The thickness of the SiO₂ oxide layer can be measured using ellipsometry, or by using secondary ion man spectrometromy (SIMS) analysis, where SIMS analysis can also make it possible to obtain the penetration depth of the doping. In contrast, in order to verify that a portion of the silicon wafer is indeed doped, measuring electrical conductivity makes it possible to verify that the second doping operation has indeed reached the silicon wafer through the oxide layer, and that there does indeed exist a non-doped zone between the doped first portions and the doped second portions, which is the purpose of the present invention.

It can be understood that various modifications and/or improvements obvious to the person skilled in the art can be applied to the various implementations of the invention as described in the present description without going beyond the ambit of the invention as defined by the accompanying claims.

1. A method of fabricating a photovoltaic cell by doping a silicon wafer, the method comprising the steps of:
performing a first doping operation of at least a first portion of a surface of the silicon wafer;
forming an oxide layer on the partially doped surface, said oxide layer covering both said first portion and another portion of said surface of said silicon wafer; and
performing a second doping operation through the oxide layer, so as to dope said another portion of the surface of the silicon wafer.

2. A method according to claim 1, wherein a step of forming an oxide layer is included in a step of activation annealing the doped first portion.

3. A method according to claim 1, wherein the step of forming an oxide layer comprises a step of heating in an oxygen-enriched atmosphere.

4. A method according to claim 1, wherein the step of performing the second doping operation comprises performing doping to a predetermined penetration depth (P).

5. A method according to claim 4,
wherein the step of forming an oxide layer comprises forming a first thickness of oxide in register with the doped first portion and a second thickness of oxide over the remainder of the surface, the second thickness of oxide being less that the first thickness of oxide; and
wherein the penetration depth lies between the first thickness of oxide and the second thickness of oxide.

6. A method according to claim 1, wherein at least one of the first doping operation and the second doping operation is performed in plasma immersion.

7. A method according to claim 1, wherein the step of performing the second doping operation is followed by a step of activation annealing the second doping.

8. A method according to claim 1, wherein:
the step of performing the first doping operation is a step of doping the silicon with a first species that requires activation annealing at a first temperature; and
the step of performing the second doping operation is a step of doping the silicon with a second species that requires activation annealing at a second temperature, lower than the first temperature.

9. A method according to claim 8, wherein:
the step of performing the first doping operation is a step of doping the silicon with boron; and
the step of performing the second doping operation is a step of doping the silicon with phosphorus.

10. A method according to claim 1, wherein the step of performing a second doping operation is followed by a step of removing the oxide layer.

11. A method according to claim 10, wherein the step of removing the oxide layer is a step of chemical deoxidation in a bath comprising hydrofluoric acid.
